(19) United States
(12) Patent Application Publication
(10) Pub. No.: US 2022/0254971 A1
(43) Pub. Date: Aug. 11, 2022

(54) INORGANIC ULTRAVIOLET LED DEVICE AND PREPARATION METHOD

(71) Applicant: SOUTH CHINA UNIVERSITY OF TECHNOLOGY, Guangzhou, Guangdong (CN)

(72) Inventors: Zongtao LI, Guangzhou, Guangdong (CN); Xinrui DING, Guangzhou, Guangdong (CN); Hanguang LU, Guangzhou, Guangdong (CN); Yong TANG, Guangzhou, Guangdong (CN); Kai CAO, Guangzhou, Guangdong (CN); Longshi RAO, Guangzhou, Guangdong (CN); Hong WANG, Guangzhou, Guangdong (CN)

(21) Appl. No.: 17/625,375

(22) PCT Filed: Jul. 10, 2020
(86) PCT No.: PCT/CN2020/101225

§ 371 Date: Jan. 7, 2022

(30) Foreign Application Priority Data
Jul. 10, 2019 (CN) 201910618692.9

(51) Int. Cl. H01L 33/62; H01L 33/58; H01L 33/00; H01L 33/44

(52) U.S. Cl. CPC H01L 33/62; H01L 33/58; H01L 2933/0025; H01L 33/44; H01L 2933/0066; H01L 33/005

(57) ABSTRACT

An inorganic ultraviolet LED device, includes a bracket, a curved lens, a press ring, a wire and an ultraviolet chip. A “T”-shaped recess is formed on the upper end of the bracket. The ultraviolet chip is fixed within the recess and connected to a welding layer at the lower end of the bracket through the wire. The curved lens is placed on a step of the recess. An inclined surface is formed on a contact surface of the step contacting with the curved lens. One end of the press ring is connected to the bracket, and the other end thereof presses against the curved lens. Deformation of the press ring is implemented under a pressure action of a pressure head, thereby implementing high-strength bonding of the device. Self-positioning is achieved through a curved surface of the lens and the contact with the inclined surface of the bracket.

### TECHNICAL FIELD

The present disclosure relates to the field of manufacturing optical devices, in particular to an inorganic ultraviolet LED device and a preparation method thereof.

### BACKGROUND ART

The light emission of ultraviolet LED chips is similar to Lambert distribution. The light intensity is distributed according to a cosine law, which cannot be directly applied to illumination, and secondary optical structures such as curved lens are needed to control the light distribution. In the traditional LED device, the curved lens is fixed by assembling a pressure ring and a lens barrel, and organic materials such as glue are needed to bond the lenses. However, ultraviolet light will decompose and age the organic materials, thus reducing the bonding effect and affecting the service life of the device. Furthermore, there are many types of lenses with different surface curvature. The fixing method using the pressure ring and the lens barrel has low precision and poor stability, which easily causes the lens to shift and dislocate. The uneven stress of the lens also easily leads to the surface damage, which affects the light intensity distribution of the device.

### SUMMARY

The purpose of the present disclosure is to overcome the shortcomings of the prior art and provide an inorganic ultraviolet LED device. The present disclosure can solve the problems that traditional lenses are easy to age, have a low precision and a low stability due to usage of adhesive.

Furthermore, the present disclosure further provides a preparation method of an inorganic ultraviolet LED device.

The purpose of the present disclosure can be achieved by the following technical solution.

An inorganic ultraviolet LED device includes a bracket, a curved lens, a pressure ring, a wire and an ultraviolet chip. An upper end of the bracket is provided with a T-shaped recess. The ultraviolet chip is fixed in the recess and connected with a welding layer through a wire. The welding layer is located at a lower end of the bracket. The curved lens is placed on a step of the recess. A contact surface of the step contacting with the curved lens is polished into an inclined surface, and the pressure ring is fixed to the curved lens and the upper end of the bracket. Under the pressure of the pressure head, the deformation of the pressure ring is realized, so that the curved lens and the bracket are combined with high strength. The self-positioning is completed by contacting the curved surface of the curved lens with the inclined surface of the bracket, so that the lens is fixed in this way. The bonding strength is high and the stability is good. Furthermore, the use of organic material such as glue is avoided, the decomposition effect of ultraviolet light on the organic material is prevented, thereby improving the service life of ultraviolet LED devices.

In some embodiments, a slope of the inclined surface is within a range of 30-45 degrees.

In some embodiments, a side of the curved lens is roughened by grinding of metal sand. The bonding strength between the pressure ring and the lens is improved by roughening. In some embodiments, the lower curved surface of the curved lens is a free curved surface, which can better contact with the inclined surface of the bracket to complete the self-positioning of the lens.

In some embodiments, a contact surface of the bracket contacting with the pressure ring is coated with a zinc-aluminum coating. The coating and the aluminum alloy pressure ring are welded under the pressure of an annular pressure head, thereby having a high bonding strength and a good stability.

In some embodiments, the pressure ring is made of 1-series aluminum alloy. The aluminum alloy has good plasticity and ductility, and is easy to process. The surface of the aluminum alloy can realize intermolecular bonding with other metals under the pressure of the pressure head to complete high-strength welding. Therefore, the aluminum alloy is suitable for fixing and installing the curved lens.

A preparation method of an inorganic ultraviolet LED device includes the steps of:

1) degreasing a contact surface of a bracket contacting with a pressure ring by a degreasing agent, uniformly coating the contact surface with zinc-aluminum coating solution, pre-baking in an oven and sintering;

2) fixing an ultraviolet chip in a recess of the bracket, and welding the ultraviolet chip with a welding layer of the bracket by using a wire;

3) grinding and roughening a side surface of the curved lens with carborundum, placing the curved lens right above the ultraviolet chip, and contacting a lower curved surface of the curved lens with an inclined surface of the bracket to implement self-positioning of the curved lens; and

4) placing the pressure ring between the lens and the bracket, applying by an annular pressure head a longitudinal pressure to the pressure ring at a certain frequency to deform the pressure ring, and obtain a shape of the pressure ring matching the side surface and an upper curved surface of the curved lens.

In some embodiments, in the degreasing a contact surface of a bracket contacting with a pressure ring by a degreasing agent, a coating thickness of the zinc-aluminum coating solution is within a range of 25-75 a pre-baking temperature is within a range of 70-95° C., a pre-baking time is within a range of 7-10 min, a sintering temperature is within a range of 150-200° C., and a sintering time is within a range of 40-70 min.

In some embodiments, a mesh number of the carborundum is between 10 and 20, a grinding speed is between 5 and 15 m/min, and a grinding pressure is between 1.5 and 3 kg/cm².

In some embodiments, an outer diameter of the annular pressure head is 0.1-0.2 mm smaller than that of the pressure ring before deformation, a pressure of the annular pressure head is within a range of 15-20 MPa, a stroke of the annular pressure head is within a range of 15-30 mm, and a pressure holding time is 1.0-2.5 s.

Compared with the prior art, the present disclosure has the following advantages and beneficial effects:

1. In the present disclosure, the deformation of the pressure ring is realized through the pressure action, so that the devices are combined with high strength. The self-positioning is completed by contacting the curved surface of the curved lens with the inclined surface of the bracket, so that the lens is fixed in this way, the bonding strength between the bracket and the lens is high and the stability is good. Furthermore, the use of organic material such as adhesive is avoided, the decomposition effect of ultraviolet light on the organic material is prevented, and the service life of the ultraviolet LED device is prolonged.

2. In the present disclosure, the deformation of the aluminum alloy by the pressure head is utilized to complete the installation and fixation process of the lens, and the aluminum alloy has high matching degree with the curved surface of the lens, thereby avoiding the problem of lens dislocation.

3. In the present disclosure, a layer of zinc-aluminum alloy coating is pre-sintered on the bracket, which is welded with the aluminum alloy pressure ring under the pressure of the annular pressure head, thereby having a high bonding strength and a good bonding stability between the bracket and the lens.

### BRIEF DESCRIPTION OF THE DRAWINGS

FIG. 1 is a schematic structural diagram of an inorganic ultraviolet LED device according to the present disclosure;

FIG. 2 is a schematic structural diagram of a bracket according to the present disclosure;

FIG. 3 is a partial enlarged diagram of a part A in FIG. 2;

FIG. 4 is a schematic structural diagram of a curved lens according to the present disclosure;

FIG. 5 is a partial enlarged diagram of a part B in FIG. 4;

FIG. 6 is a schematic diagram after fixing a crystal seed wire in step 2 of a preparation method according to the present disclosure;

FIG. 7 is a schematic diagram of placing a lens in step 3 of the preparation method according to the present disclosure;

FIG. 8 is a schematic diagram of placing a pressure ring in step 4 of the preparation method according to the present disclosure;

FIG. 9 is a schematic diagram showing a deformed pressure ring in step 4 of the preparation method according to the present disclosure;

FIG. 10 is a schematic structural diagram according to embodiment 5 of the present disclosure.

List of reference numbers: 1 lens, 2 pressure ring, 3 bracket, 31 recess, 4 ultraviolet chip, 5 wire, 6 welding layer, 7 contact surface of bracket contacting with pressure ring, 8 side surface of curved lens, 9 metal baffle.

### DETAILED DESCRIPTION OF THE EMBODIMENTS

The present disclosure will be described in further detail with reference to embodiments and drawings, but the embodiments of the present disclosure are not limited thereto.

### Embodiment 1

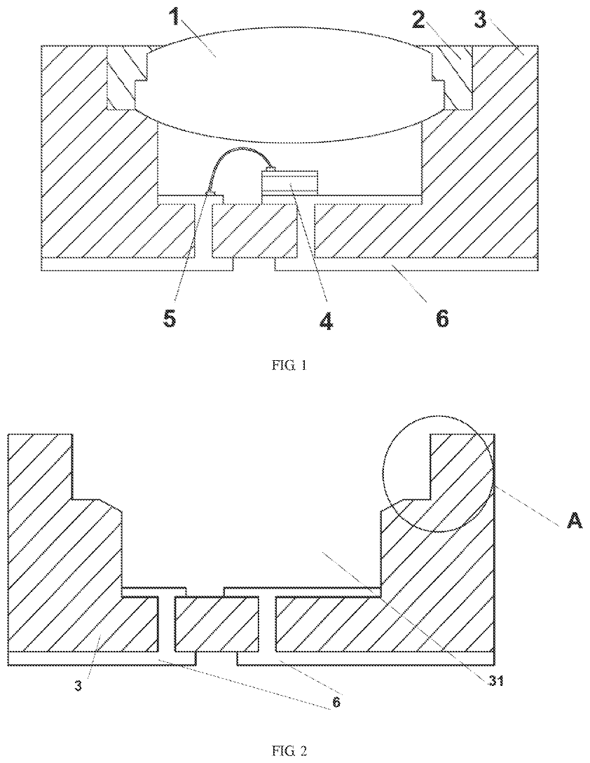

As shown in FIGS. 1 and 2, an inorganic ultraviolet LED device comprises a bracket 3, a curved lens 1, a pressure ring 2, and an ultraviolet chip 4. An upper end of the bracket 3 is provided with a T-shaped recess 31. The ultraviolet chip 4 is fixed in the recess 31. The ultraviolet chip 4 is connected with a welding layer 6 at a bottom end of the bracket 3 through the wire 5. The curved lens 1 is placed on a step of the recess 31. A contact surface of the step contacting with the curved lens 1 is a polished inclined surface. One end of the pressure ring 2 abuts against the bracket 3, and the other end of the pressure ring 2 presses the curved lens 1 tightly. Under a pressure of a pressure head, the deformation of the pressure ring 2 is realized, so that the devices are combined with high strength. A self-positioning is completed by contacting the curvature of the curved surface of the curved lens 1 with the inclined surface of the bracket 3, so that the curved lens 1 is fixed in this way, the bonding strength between the curved lens and the bracket is high and the stability is good. Furthermore, the use of organic material such as adhesive is avoided, the decomposition effect of ultraviolet light on the organic material is prevented, thereby improving a service life of the ultraviolet LED device.

A slope of the inclined surface is 30 degrees.

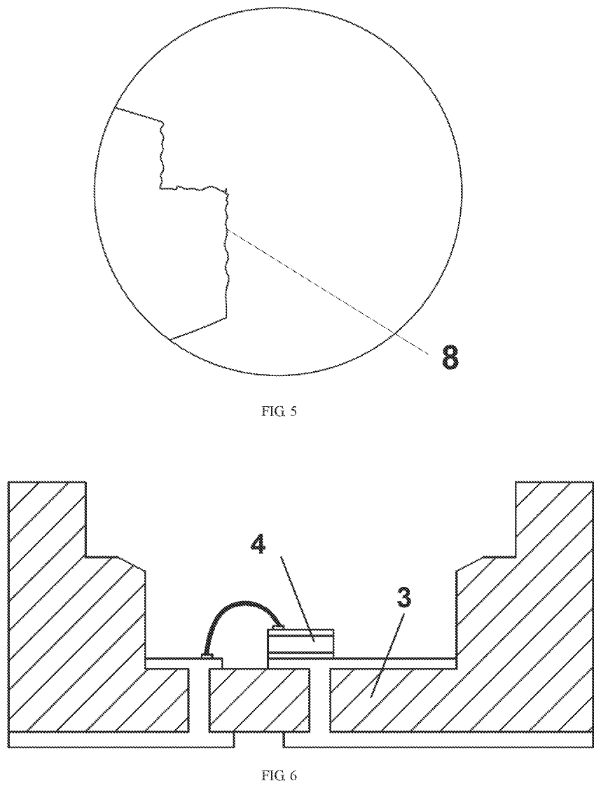

As shown in FIGS. 4 and 5, the side of the curved lens is roughened by grinding of metal sand. The bonding strength between the pressure ring and the lens is improved by roughening. A lower curved surface of the curved lens 1 is a free curved surface, which can better contact with the inclined surface of the bracket 3 to complete the self-positioning of the lens.

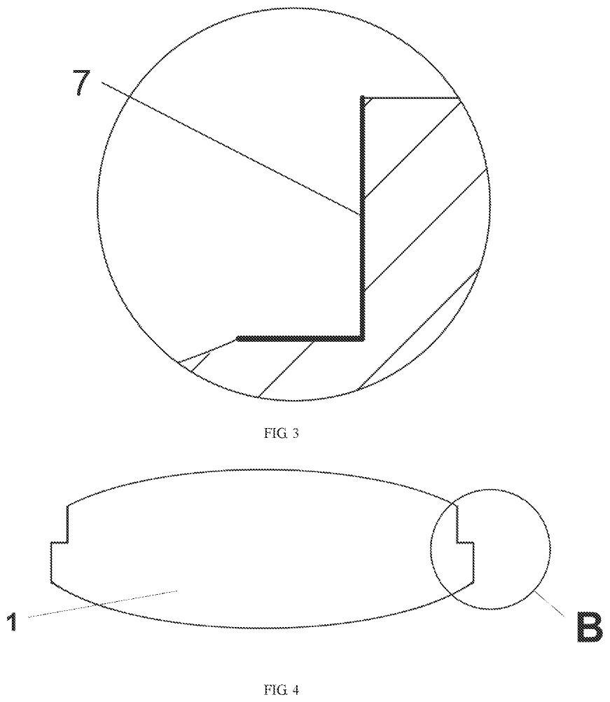

As shown in FIG. 3, the contact surface of the bracket 3 contacting with the pressure ring 2 is coated with a zinc-aluminum coating. The zinc-aluminum coating and the aluminum alloy pressure ring are welded under the pressure of an annular pressure head; therefore, the bonding strength between the bracket and the pressure ring is high and the bonding stability is good.

The pressure ring 2 is made of 1-series aluminum alloy.

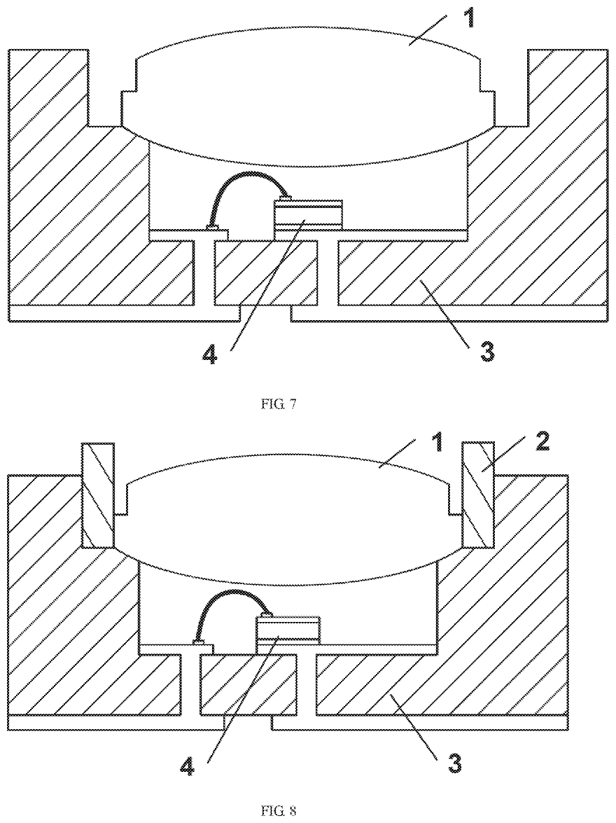

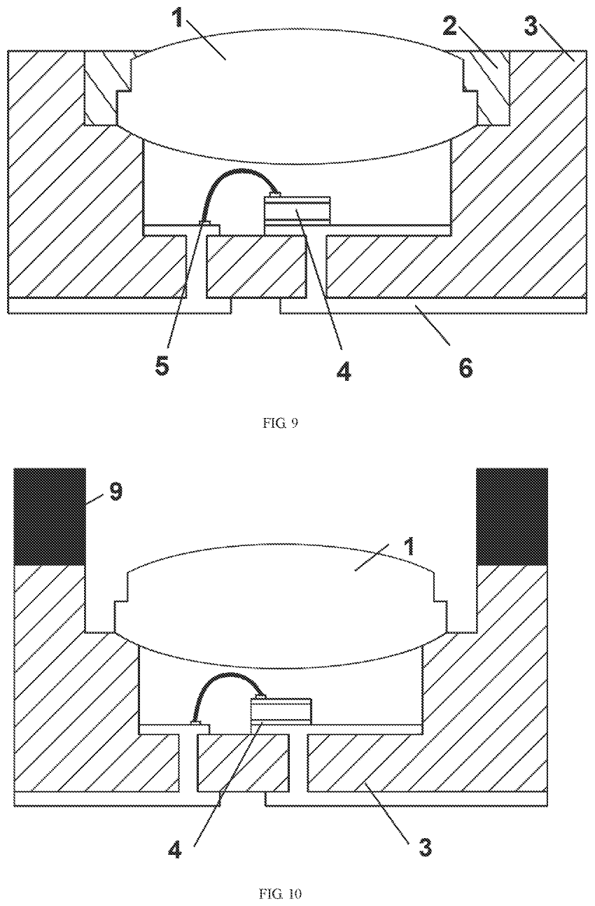

As shown in FIGS. 6-9, a preparation method of the inorganic ultraviolet LED device includes the steps of:

1) degreasing a contact surface 7 of the bracket 3 contacting with the pressure ring 2 by a degreasing agent, uniformly coating the contact surface with a zinc-aluminum coating solution with a thickness of 55 μm, pre-baking the coated contact surface in an oven at 80° C. for 8 min, and sintering it in an oven at 185° C. for 60 min;

2) fixing the ultraviolet chip 4 in the recess 31 of the bracket, and simultaneously welding the ultraviolet chip 4 with the welding layer 6 of the bracket 3 by a wire 5;

3) grinding and roughening the side surface 8 of the curved lens 1 with carborundum, wherein the grinding speed and the pressure are 10 m/min and 2.1 kg/cm², respectively, placing the curved lens 1 right above the ultraviolet chip 4, and completing the self-positioning of the lens through the contact between the lower curved surface of the curved lens 1 and the inclined surface of the bracket 3;

4) placing the pressure ring 2 between the lens 1 and the bracket 3, applying a longitudinal pressure to the pressure ring 2 through the annular pressure head at a certain frequency to deform the pressure ring, and obtaining a shape matching the side surface and the upper curved surface of the curved lens 1. The outer diameter of the annular pressure head is 0.15 mm smaller than that of the pressure ring before deformation, the pressure of the pressure head is 16 MPa, the stroke of the pressure head is 20 mm, and the pressure holding time is 1.5 s.

### Embodiment 2

This embodiment is the same as Embodiment 1 except for the following technical features.

In step 2), after being ground and roughened, the side 8 of the lens is coated with 40 μm of zinc-aluminum coating solution, the coated side 8 is pre-baked at 95° C. for 10 min, and then sintered at 200° C. for 70 min to complete the sintering of the zinc-aluminum alloy coating on the side of the lens.

### Embodiment 3

This embodiment is the same as Embodiment 2 except for the following technical features.

In step 4), the annular pressure head is changed into an ultrasonic welding head with a vibration frequency of 18 kHz, which can improve the bonding strength of aluminum alloy.

### Embodiment 4

This embodiment is the same as Embodiment 3 except for the following technical features.

In step 3), after the pressure ring is deformed, the upper surface of the bracket is ground to remove excess aluminum alloy flowing to the outer side of the bracket.

### Embodiment 5

This embodiment is the same as Embodiment 4 except for the following technical features.

As shown in FIG. 10, in step 3), after grinding and roughening the side 8 of the curved lens 1, a metal baffle 9 is placed at the upper end of the bracket adjacent to the pressure ring to prevent metal overflow when the pressure ring is deformed. The inner diameter of the metal baffle is 0.15 mm larger than the outer diameter of the pressure ring before deformation. In step 4), the metal baffle is removed after the pressure ring is deformed.

The above specific embodiments are preferred embodiments of the present disclosure, and the present disclosure cannot be limited. Any other changes or other equivalent substitutions made without deviating from the technical scheme of the present disclosure are included in the protection scope of the present disclosure.

What is claimed is:

1. An inorganic ultraviolet LED device, comprising a bracket, a curved lens, a pressure ring, a wire and an ultraviolet chip, wherein an upper end of the bracket is provided with a T-shaped recess, the ultraviolet chip is fixed in the recess and connected with a welding layer through the wire, the welding layer is located at a lower end of the bracket, the curved lens is placed on a step of the recess, a contact surface of the step contacting with the curved lens is polished into an inclined surface, and the pressure ring is fixed to the curved lens and the upper end of the bracket.

2. The inorganic ultraviolet LED device according to claim 1, wherein a slope of the inclined surface is within a range of 30-45 degrees.

3. The inorganic ultraviolet LED device according to claim 1, wherein a side of the curved lens is roughened by grinding of metal sand.

4. The inorganic ultraviolet LED device according to claim 1, wherein a lower curved surface of the curved lens is a free curved surface.

5. The inorganic ultraviolet LED device according to claim 1, wherein a contact surface of the bracket contacting with the pressure ring is coated with a zinc-aluminum coating.

6. The inorganic ultraviolet LED device according to claim 1, wherein the pressure ring is made of 1-series aluminum alloy.

7. A preparation method of an inorganic ultraviolet LED device, comprising steps of:
degreasing a contact surface of a bracket contacting with a pressure ring by a degreasing agent, uniformly coating the contact surface with zinc-aluminum coating solution, pre-baking in an oven and sintering;
fixing an ultraviolet chip in a recess of the bracket, and welding the ultraviolet chip with a welding layer of the bracket by using a wire;
grinding and roughening a side surface of the curved lens with carborundum, placing the curved lens right above the ultraviolet chip, and contacting a lower curved surface of the curved lens with an inclined surface of the bracket to implement self-positioning of the curved lens;
placing the pressure ring between the lens and the bracket, applying by an annular pressure head a longitudinal pressure to the pressure ring at a certain frequency to deform the pressure ring, and obtain a shape of the pressure ring matching the side surface and an upper curved surface of the curved lens.

8. The preparation method of the inorganic ultraviolet LED device according to claim 7, wherein in the degreasing a contact surface of a bracket contacting with a pressure ring by a degreasing agent, a coating thickness of the zinc-aluminum coating solution is within a range of 25-75 μm, a pre-baking temperature is within a range of 70-95° C., a pre-baking time is within a range of 7-10 min, a sintering temperature is within a range of 150-200° C., and a sintering time is within a range of 40-70 min.

9. The preparation method of the inorganic ultraviolet LED device according to claim 7, wherein a mesh number of the carborundum is between 10 and 20, a grinding speed is between 5 and 15 m/min, and a grinding pressure is between 1.5 and 3 kg/cm².

10. The preparation method of the inorganic ultraviolet LED device according to claim 7, wherein an outer diameter of the annular pressure head is 0.1-0.2 mm smaller than that of the pressure ring before deformation, a pressure of the annular pressure head is within a range of 15-20 MPa, a stroke of the annular pressure head is within a range of 15-30 mm, and a pressure holding time is 1.0-2.5 s.
